(19) United States
(12) Patent Application Publication
(10) Pub. No.: US 2025/0096118 A1
(43) Pub. Date: Mar. 20, 2025

(54) SEMICONDUCTOR DEVICE

(71) Applicant: Kioxia Corporation, Tokyo (JP)

(72) Inventor: Kunio OTA, Yokohama (JP)

(73) Assignee: Kioxia Corporation, Tokyo (JP)

(21) Appl. No.: 18/769,508

(22) Filed: Jul. 11, 2024

(30) Foreign Application Priority Data
Sep. 15, 2023 (JP) 2023-150146

(51) Int. Cl. H01L 23/522; H01L 23/00; H01L 23/31; H01L 23/498; H01L 23/64; H01L 25/065; H01L 25/18

(52) U.S. Cl. CPC H01L 23/5227; H01L 23/3128; H01L 23/49816; H01L 23/642; H01L 24/48; H01L 24/49; H01L 25/0657; H01L 25/18; H10D 1/20; H01L 2224/48225; H01L 2224/48245; H01L 2224/49112

(57) ABSTRACT

A semiconductor device includes an interposer substrate including a plurality of wiring layers inside, a first semiconductor chip disposed on the interposer substrate, and a power circuit configured to transform externally supplied voltage and supply the transformed voltage to the first semiconductor chip. The power circuit includes an inductor and a capacitor, the inductor being constituted by a plurality of coil patterns respectively formed in at least two of the plurality of wiring layers.

### CROSS-REFERENCE TO RELATED APPLICATION

This application is based upon and claims the benefit of priority from the prior Japanese Patent Applications No. 2023-150146, filed on Sep. 15, 2023, the entire contents of which are incorporated herein by reference.

### FIELD

Embodiments relate to a semiconductor device.

### BACKGROUND

A semiconductor device in which a semiconductor memory chip and a semiconductor controller chip are built has been known.

### BRIEF DESCRIPTION OF THE DRAWINGS

FIG. 1 is a front view illustrating the front structure of a semiconductor device of a first embodiment;

FIG. 2 is a plan view illustrating the planar structure of the semiconductor device of the first embodiment;

FIG. 3 is a sectional view illustrating a sectional structure along line III-III in FIG. 2;

FIG. 4 is a circuit diagram illustrating the configuration of a power circuit of the first embodiment;

FIGS. 5A to 5D are diagrams schematically illustrating the planar structures of a plurality of coil patterns included in an inductor of the first embodiment;

FIG. 6 is a perspective view schematically illustrating the perspective structure of the inductor of the first embodiment;

FIGS. 7A to 7D are diagrams schematically illustrating the planar structures of a plurality of coil patterns included in an inductor of a modification of the first embodiment;

FIG. 8 is a front view illustrating the front structure of a semiconductor device of a second embodiment;

FIG. 9 is a circuit diagram illustrating the configuration of a power circuit of a third embodiment;

FIG. 10 is a front view illustrating the front structure of a semiconductor device of the third embodiment; and

FIG. 11 is a plan view illustrating the planar structure of the semiconductor device of the third embodiment.

### DETAILED DESCRIPTION

In general, according to one embodiment, a semiconductor device comprises: an interposer substrate including a plurality of wiring layers inside; a first semiconductor chip disposed on the interposer substrate; and a power circuit configured to transform externally supplied voltage and supply the transformed voltage to the first semiconductor chip. The power circuit includes: an inductor constituted by a plurality of coil patterns respectively formed in at least two of the plurality of wiring layers of the interpose substrate; and a capacitor.

Embodiments will be described below with reference to the accompanying drawings. To facilitate the understanding of descriptions, identical constituent components in the drawings are denoted by the same reference sign whenever possible, and duplicate description thereof is omitted.

### 1 First Embodiment

A semiconductor device of a first embodiment will be described below. The semiconductor device of the present embodiment is a semiconductor package including a NAND flash memory chip. The semiconductor device of the present embodiment is, for example, a universal flash storage (UFS) device configured to be mounted on a smartphone.

### 1.1 Configuration of Semiconductor Device

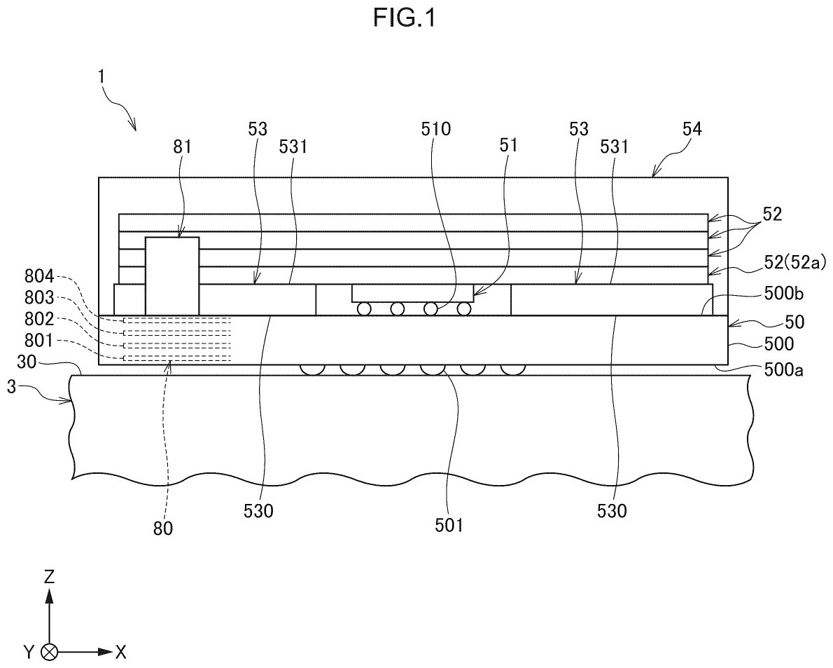

FIG. 1 is a front view illustrating the front structure of a semiconductor device 1 of the present embodiment. As illustrated in FIG. 1, the semiconductor device 1 can be mounted on a substrate 3.

The substrate 3 is, for example, a printed circuit board (PCB). The semiconductor device 1 can be mounted on a surface 30 of the substrate 3. In the following descriptions, a direction orthogonal to the surface 30 of the substrate 3 is referred to as a Z direction. In addition, axial directions orthogonal to the Z direction and orthogonal to each other are referred to as an X direction and a Y direction. The Z direction is an example of a first direction.

The semiconductor device 1 includes an interposer substrate 50, a controller chip 51, a plurality of memory chips 52, one or more spacers 53, and a sealing member 54. The semiconductor device 1 is a semiconductor package in which the controller chip 51, the plurality of memory chips 52, and the like are integrally sealed by the sealing member 54. FIG. 1 illustrates a cut sectional structure of the sealing member 54 with a portion cut off, but hatching that represents a cut section of the sealing member 54 is omitted. In the other diagrams as well, hatching that represents a cut section of the sealing member 54 is omitted.

The interposer substrate 50 is disposed between the substrate 3 and the controller chip 51. The interposer substrate 50 includes a multi-layer structure 500 and a plurality of external terminals 501. The interposer substrate 50 is used to establish electrical conduction among the substrate 3, the controller chip 51, and the memory chips 52.

The multi-layer structure 500 includes a plurality of insulating layers, a plurality of wiring layers, and a via. The multi-layer structure 500 has a structure in which the insulating and wiring layers are alternately stacked in the Z direction. The multi-layer structure 500 of the present embodiment includes four wiring layers. The plurality of wiring layers are electrically connected to each other through the via penetrating one or more of the plurality of insulating layers in the Z direction. The insulating layers are formed of an insulation material such as resin that contains glass. The wiring layers and the via are formed of a conductive material such as copper (Cu).

The multi-layer structure 500 has a bottom surface 500a. The bottom surface 500a faces the substrate 3. The plurality of external terminals 501 are provided on the bottom surface 500a. The plurality of external terminals 501 are electrically connected to at least one of the plurality of wiring layers formed inside the multi-layer structure 500 through electrodes formed on the bottom surface 500a. The external terminals 501 are protruding terminals formed of solder balls, solder plating, or the like. A bottom part of each of the plurality of external terminals 501 contacts an electrode provided on the substrate 3. Accordingly, circuits inside the substrate 3 are electrically connected to the wiring layers inside the multi-layer structure 500.

The multi-layer structure 500 has an upper surface 500b. The upper surface 500b faces the controller chip 51. The upper surface 500b contacts a plurality of external terminals 510 formed on the controller chip 51. The upper surface 500b is provided with a plurality of electrodes that the plurality of external terminals 510 of the controller chip 51 respectively contact. The controller chip 51 is electrically connected to circuits inside the substrate 3 through the external terminals 510, the electrodes formed on the upper surface 500b, the wiring layers formed inside the multi-layer structure 500, the electrodes formed on the bottom surface 500a, the external terminals 501, and electrodes provided on the substrate 3.

In the following description, the bottom surface 500a of the multi-layer structure 500 is also referred to as the bottom surface 500a of the interposer substrate 50, and the upper surface 500b of the multi-layer structure 500 is also referred to as the upper surface 500b of the interposer substrate 50. In the present embodiment, the upper surface 500b of the interposer substrate 50 corresponds to a principal surface of the interposer substrate 50.

The controller chip 51 includes the plurality of external terminals 510. The controller chip 51 is, for example, a system-on-a-chip (SoC) or an application specific integrated circuit (ASIC). The controller chip 51 may be any other integrated circuit (IC) or circuit. The controller chip 51 is an example of a first semiconductor chip.

The plurality of memory chips 52 are disposed as a stack above the controller chip 51. The memory chips 52 are disposed apart from the upper surface 500b of the interposer substrate 50 in the Z direction. The disposition of the controller chip 51 and the memory chips 52 is exemplary and optionally changeable.

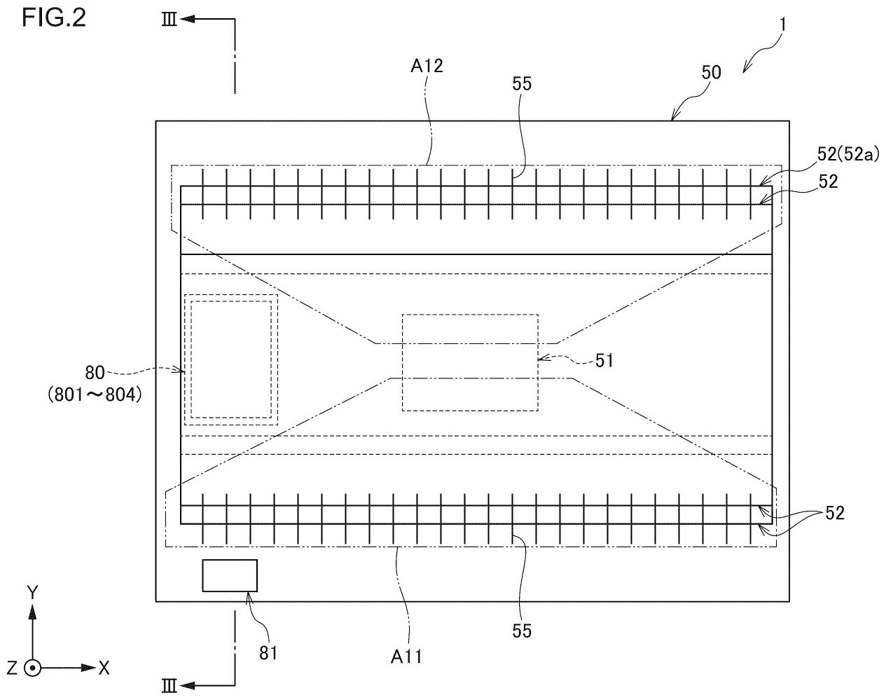

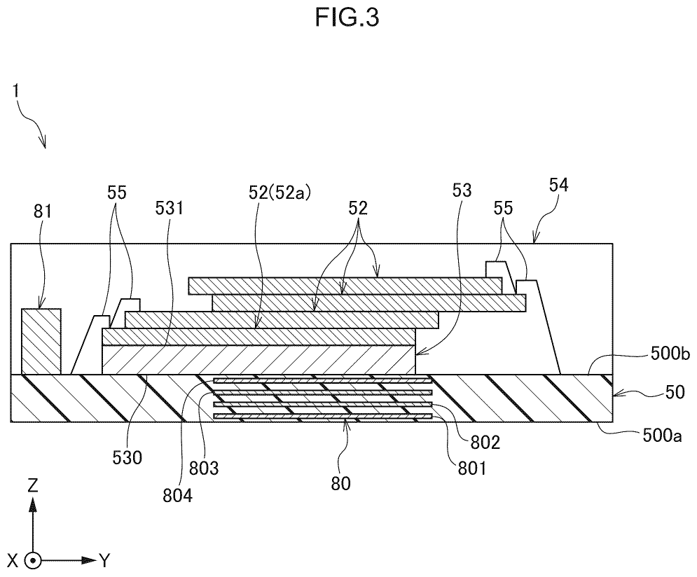

FIG. 2 is a plan view illustrating the planar structure of the semiconductor device 1. FIG. 3 is a sectional view illustrating a sectional structure along line III-III in FIG. 2.

As illustrated in FIGS. 2 and 3, the semiconductor device 1 further includes bonding wires 55 connecting the plurality of memory chips 52 to the interposer substrate 50. The plurality of memory chips 52 are electrically connected to the controller chip 51 through the bonding wires 55, the wiring layers inside the interposer substrate 50, and the external terminals 510.

As illustrated in FIGS. 1 and 3, the spacer 53 is disposed between a lower end memory chip 52a, which is disposed at a position closest to the interposer substrate 50 among the plurality of memory chips 52, and the upper surface 500b of the interposer substrate 50. The upper surface 500b of the interposer substrate 50 is bonded to a bottom surface 530 of the spacer 53 in the Z direction through a bonding layer. A bottom surface of the lower end memory chip 52a is bonded to an upper surface 531 of the spacer 53 in the Z direction through a bonding layer.

The sealing member 54 is formed of, for example, synthesis resin. The sealing member 54 seals the controller chip 51, the plurality of memory chips 52, the plurality of bonding wires 55, and the spacers 53.

### 1.2 Configuration of Power Circuit

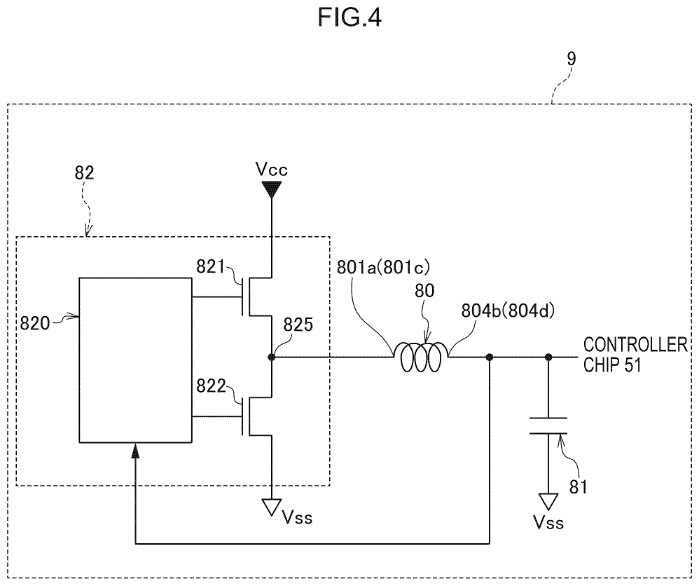

The semiconductor device 1 of the present embodiment further includes a power circuit 9 illustrated in FIG. 4. FIG. 4 is a circuit diagram illustrating the configuration of the power circuit 9 according to the present embodiment. The power circuit 9 adjusts externally supplied voltage and supplies the adjusted voltage to the controller chip 51. The power circuit 9 transforms (for example, steps down) the externally supplied voltage. For example, the power circuit 9 is a DC/DC converter. The stepped-down voltage is supplied to a low-voltage system such as a logic power source or an I/O power source of the controller chip 51. For example, in a case where the externally supplied voltage is 2.5 V, the power circuit 9 steps down the voltage to 1.2 V.

A specific configuration of the power circuit 9 will be described below. As illustrated in FIG. 4, the power circuit 9 includes an inductor 80, a capacitor 81, and a power device 82.

The power device 82 is built in the controller chip 51. The power device 82 includes a control circuit 820 and two switching elements 821 and 822.

The two switching elements 821 and 822 are, for example, N-channel MOS transistors. The source terminal of the switching element 821 and the drain terminal of the switching element 822 are connected to each other. Accordingly, the two switching elements 821 and 822 are electrically connected in series to each other. Externally supplied voltage Vcc is applied to the drain terminal of the switching element 821. The external voltage Vcc is supplied from the substrate 3 to the controller chip 51 through the external terminals 501, the wiring layers of the interposer substrate 50, and the external terminals 510, which are illustrated in FIG. 1. Ground voltage Vss is supplied to the source terminal of the switching element 822.

As illustrated in FIGS. 1 and 3, the inductor 80 is constituted by a plurality of coil patterns 801 to 804 formed in the interposer substrate 50. The coil patterns 801 to 804 are formed in the four wiring layers, respectively, included in the interposer substrate 50. The coil patterns 801 to 804 are formed of a conductive material such as copper (Cu).

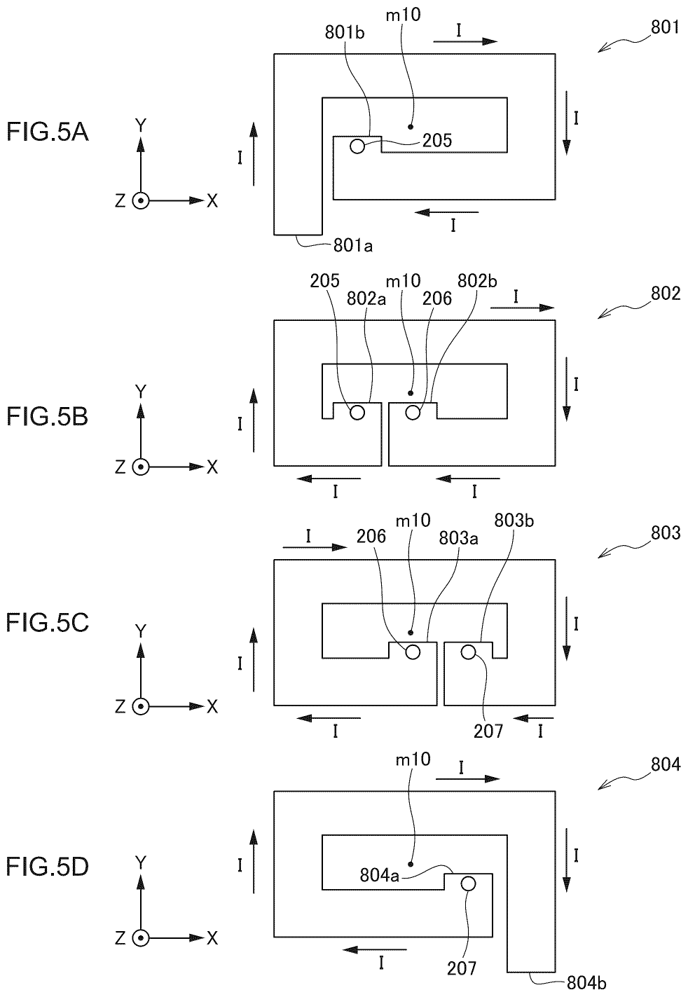

FIGS. 5A to 5D are plan views respectively illustrating the planar structures of the coil patterns 801 to 804. As illustrated in FIG. 5A, the coil pattern 801 is formed to extend in a rectangular shape bending around an axis line m10. The axis line m10 is an axis line parallel to the Z direction. As illustrated in FIG. 4, a first end part 801a of the coil pattern 801 is connected to an intermediate part 825 between the switching elements 821 and 822 through the wiring layers of the interposer substrate 50. As illustrated in FIG. 5A, a second end part 801b of the coil pattern 801 is formed to protrude inward (to the Y direction).

As illustrated in FIG. 5B, similarly to the coil pattern 801, the coil pattern 802 is formed to extend in a rectangular shape bending around the axis line m10. A first end part 802a and a second end part 802b of the coil pattern 802 are formed to protrude inward. The first end part 802a of the coil pattern 802 is disposed at a position overlapping the second end part 801b of the coil pattern 801 illustrated in FIG. 5A when viewed from the Z direction. The first end part 802a of the coil pattern 802 is connected to the second end part 801b of the coil pattern 801 through a through-hole 205 formed to extend in the Z direction in the interposer substrate 50. The second end part 802b of the coil pattern 802 is displaced relative to the first end part 802a in the X direction.

As illustrated in FIG. 5C, similarly to the coil pattern 801, the coil pattern 803 is formed to extend in a rectangular shape bending around the axis line m10. A first end part 803a and a second end part 803b of the coil pattern 803 are formed to protrude inward. The first end part 803a of the coil pattern 803 is disposed at a position overlapping the second end part 802b of the coil pattern 802 illustrated in FIG. 5B when viewed from the Z direction. The first end part 803a of the coil pattern 803 is connected to the second end part 802b of the coil pattern 802 through a through-hole 206 formed to extend in the Z direction in the interposer substrate 50. The second end part 803b of the coil pattern 803 is displaced relative to the first end part 803a in the X direction.

As illustrated in FIG. 5D, similarly to the coil pattern 801, the coil pattern 804 is formed to extend in a rectangular shape bending around the axis line m10. A first end part 804a of the coil pattern 804 is formed to protrude inward. The first end part 804a of the coil pattern 804 is disposed at a position overlapping the second end part 803b of the coil pattern 803 illustrated in FIG. 5C when viewed from the Z direction. The first end part 804a of the coil pattern 804 is electrically connected to the second end part 803b of the coil pattern 803 through a through-hole 207 formed to extend in the Z direction in the interposer substrate 50. As illustrated in FIG. 4, a second end part 804b of the coil pattern 804 is electrically connected to the controller chip 51 and the capacitor 81 through the wiring layers of the interposer substrate 50.

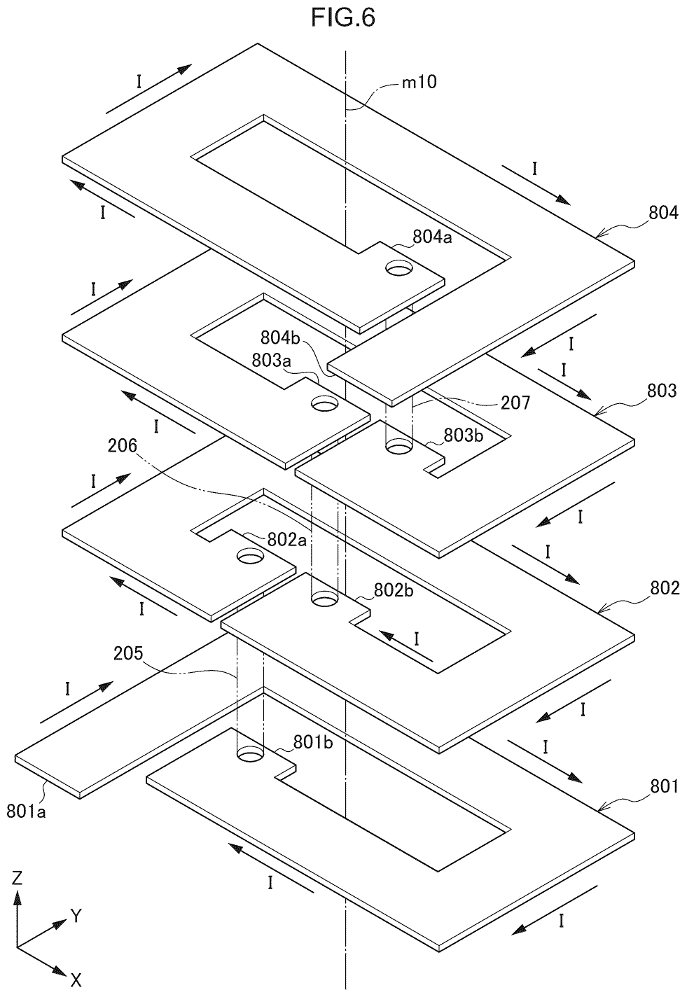

FIG. 6 is a perspective view schematically illustrating perspective structures of the coil patterns 801 to 804. As illustrated in FIG. 6, the other parts of the coil patterns 801 to 804 than the first end parts 801a to 804a and the second end parts 801b to 804b are formed to overlap one another when viewed from the Z direction. Accordingly, the coil patterns 801 to 804 have substantially identical pattern shapes.

The voltage Vcc is applied to the first end part 801a of the coil pattern 801 when the switching element 821 illustrated in FIG. 4 is turned on. Accordingly, current flowing through the coil patterns 801 to 804 increases as illustrated with arrows I in FIGS. 5A to 5D and 6. Specifically, current flows through the first end part 801a and the second end part 801b of the coil pattern 801, the through-hole 205, the first end part 802a and the second end part 802b of the coil pattern 802, the through-hole 206, the first end part 803a and the second end part 803b of the coil pattern 803, the through-hole 207, and the first end part 804a and the second end part 804b of the coil pattern 804 in the stated order.

As illustrated in FIG. 1, the coil patterns 801 to 804 are formed at a part of the interposer substrate 50 below the spacer 53. As illustrated in FIG. 2, the coil patterns 801 to 804 are disposed at positions different from (in other words, not overlapping) wiring areas A11 and A12 of the interposer substrate 50 when viewed from the Z direction. The wiring areas A11 and A12 are regions where, for example, (a1) to (a3) below are disposed.

(a1) Part of the wiring layers of the interposer substrate 50, which functions as wiring for electrically connecting the external terminals 501 on the bottom surface 500a of the interposer substrate 50 to the controller chip 51.

(a2) Part of the wiring layers of the interposer substrate 50, which functions as wiring for electrically connecting the controller chip 51 to the memory chips 52.

(a3) Part where the bonding wires 55 connecting the interposer substrate 50 to the memory chips 52 are disposed.

In this manner, when the coil patterns 801 to 804 are disposed at positions different from the wiring areas A11 and A12 in the interposer substrate 50, it is possible to easily avoid interference of the coil patterns 801 to 804 with various wires.

The capacitor 81 illustrated in FIGS. 1 and 2 is provided on the interposer substrate 50. As illustrated in FIG. 2, the capacitor 81 may be disposed at a position different from the wiring areas A11 and A12 in the interposer substrate 50 when viewed from the Z direction. The capacitor 81 has a predetermined height in the Z direction and thus is disposed to avoid interference with the memory chips 52 and the bonding wires 55. The capacitor 81 is disposed alongside the inductor 80 in the Y direction.

As illustrated in FIG. 4, output voltage from the inductor 80 is applied to the control circuit 820 through the wiring layers of the interposer substrate 50. The control circuit 820 steps down the external voltage Vcc by controlling the gate voltages of the switching elements 821 and 822 to turn on and off the switching elements 821 and 822 and supplies the stepped-down voltage to the controller chip 51. In that case, the control circuit 820 performs, for example, control by which predetermined voltage (for example, 1.2 V) is supplied to the controller chip 51.

### 1.3 Effects of Semiconductor Device of Present Embodiment

As described above, the semiconductor device 1 of the present embodiment includes the interposer substrate 50, the controller chip 51, and the power circuit 9. The interposer substrate 50 includes the plurality of wiring layers inside. The controller chip 51 is disposed on the interposer substrate 50. The power circuit 9 transforms the external voltage Vcc and supplies the transformed voltage to the controller chip 51. The power circuit 9 includes the inductor 80 and the capacitor 81. The inductor 80 is constituted by the plurality of coil patterns 801 to 804 respectively formed in the plurality of wiring layers of the interposer substrate 50.

With this configuration, the inductor 80 can be disposed inside the interposer substrate 50, and thus the semiconductor device 1 can be downsized as compared to a case where a component corresponding to the inductor 80 is disposed, for example, on the upper surface 500b of the interposer substrate 50.

Four wiring layers are formed in the interposer substrate 50. The coil patterns 801 to 804 are formed in the four wiring layers, respectively. As illustrated in FIG. 6, the plurality of coil patterns 801 to 804 are disposed at positions overlapping one another when viewed from the Z direction.

With this configuration, higher magnetic coupling can be achieved with the coil patterns 801 to 804. Accordingly, high inductance can be obtained with a small area.

The inductance is proportional to the square of the number of turns of coil patterns included in the inductor 80. Consideration of the inductance requested for the inductor 80 in the power circuit 9 indicates that it is useful to form four or more wiring layers in the interposer substrate 50 and form four or more coil patterns (in other words, four or more turns).

The controller chip 51 includes the switching elements 821 and 822 of the power circuit 9 and the control circuit 820 configured to control the switching elements 821 and 822.

With this configuration, the structure of the semiconductor device 1 can be simplified as compared to a case where the switching elements 821 and 822 and the control circuit 820 are provided separately from the controller chip 51.

As illustrated in FIGS. 2 and 3, the plurality of coil patterns 801 to 804 are disposed at positions overlapping the memory chips 52 and the spacer 53 but not overlapping the controller chip 51 when viewed from the Z direction.

With this configuration, it is possible to avoid interference of wires connected to the controller chip 51, which are formed in the interposer substrate 50, with the coil patterns 801 to 804.

As illustrated in FIG. 6, current flows through the plurality of coil patterns 801 to 804 in identical rotational directions around the predetermined axis line m10.

With this configuration, when current flows through the coil patterns 801 to 804, the directions of magnetic fluxes formed with the coil patterns 801 to 804 are identical to one another, and thus higher magnetic coupling can be formed with the coil patterns 801 to 804. Accordingly, high inductance can be achieved.

### 1.4 Modification

A modification of the semiconductor device 1 of the first embodiment will be described below.

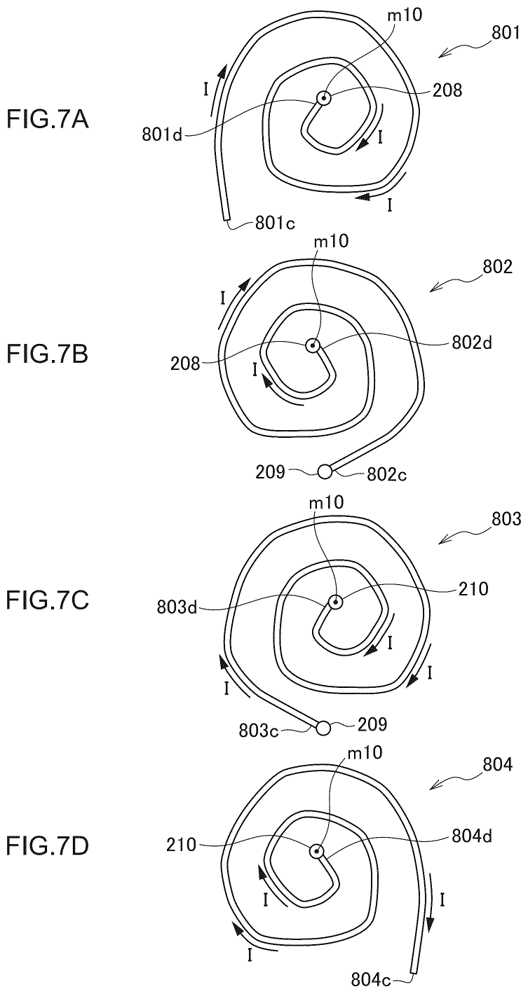

FIGS. 7A to 7D are plan views respectively illustrating the planar structures of the coil patterns 801 to 804 according to the modification. As illustrated in FIGS. 7A to 7D, the coil patterns 801 to 804 of the present modification are each formed in a swirl shape around the axis line m10. More specifically, the coil patterns 801 and 803 are each formed to swirl anticlockwise around the axis line m10. The coil patterns 802 and 804 are each formed to swirl clockwise around the axis line m10. In the following descriptions, end parts of the coil patterns 801 to 804, which are positioned at their outer peripheries are referred to as outer end part 801c, 802c, 803c, and 804c, respectively. In addition, end parts of the coil patterns 801 to 804, which are positioned near their centers are referred to as inner end parts 801d, 802d, 803d, and 804d, respectively.

As illustrated in FIG. 7A, the outer end part 801c of the coil pattern 801 is connected to the intermediate part 825, which is between the switching elements 821 and 822 as illustrated in FIG. 4. As illustrated in FIGS. 7A and 7B, the inner end part 801d of the coil pattern 801 is connected to the inner end part 802d of the coil pattern 802 through a through-hole 208. As illustrated in FIGS. 7B and 7C, the outer end part 802c of the coil pattern 802 is connected to the outer end part 803c of the coil pattern 803 through a through-hole 209. As illustrated in FIGS. 7C and 7D, the inner end part 803d of the coil pattern 803 is connected to the inner end part 804d of the coil pattern 804 through a through-hole 210. The outer end part 804c of the coil pattern 804 is connected to the controller chip 51 and the capacitor 81 as illustrated in FIG. 4 through the wiring layers of the interposer substrate 50.

In the inductor 80 of the present modification, when the switching element 821 is turned on and the voltage Vcc is applied to the outer end part 801c of the coil pattern 801, current flowing through the coil patterns 801 to 804 in the anticlockwise direction around the axis line m10 increases as illustrated with arrows I in FIGS. 7A to 7D.

With this configuration, the directions of magnetic fluxes formed with the coil patterns 801 to 804 are identical to one another, and thus higher magnetic coupling can be formed with the coil patterns 801 to 804. Accordingly, performance of the inductor 80 can be improved.

### 2 Second Embodiment

A semiconductor device of a second embodiment will be described below. The following description will be mainly made on differences from the semiconductor device 1 of the first embodiment.

### 2.1 Configuration of Semiconductor Device

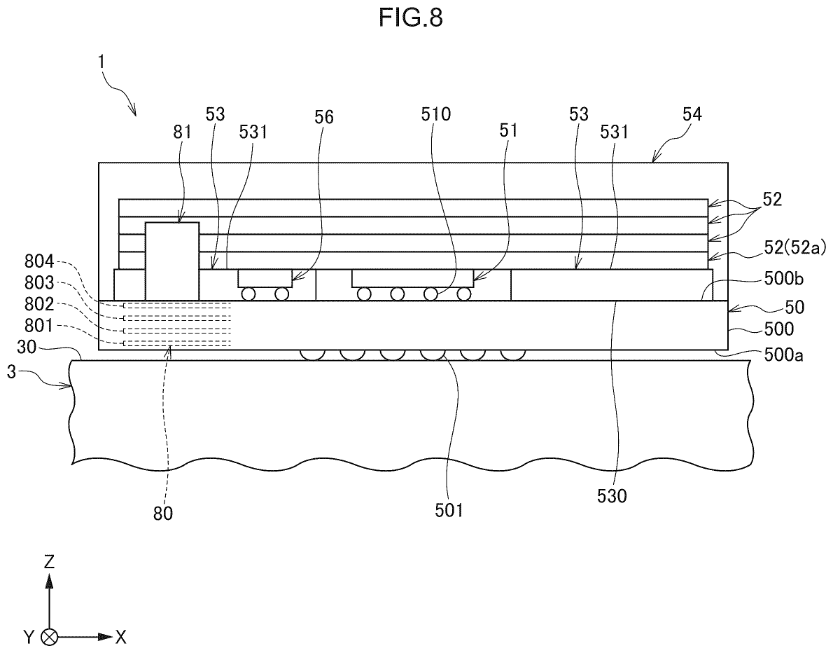

As illustrated in FIG. 8, the semiconductor device 1 of the present embodiment further includes a power source IC 56. The power source IC 56 is sealed by the sealing member 54 together with the controller chip 51, the memory chips 52, and the like. The power source IC 56 is a semiconductor chip form of the power device 82 illustrated in FIG. 3. The power source IC 56 is an example of a second semiconductor chip.

### 2.2 Effects of Semiconductor Device of Present Embodiment

The power source IC 56 of the present embodiment is provided separately from the controller chip 51 and includes the switching elements 821 and 822 and the control circuit 820.

With this configuration, it is possible to manufacture the power source IC 56 through a process suitable for the power circuit 9, and thus it is possible to improve characteristics of the power circuit 9 and reduce manufacturing cost thereof.

### 3 Third Embodiment

A semiconductor device of a third embodiment will be described below. The following description will be mainly made on differences from the semiconductor device 1 of the first embodiment.

### 3.1 Configuration of Power Circuit

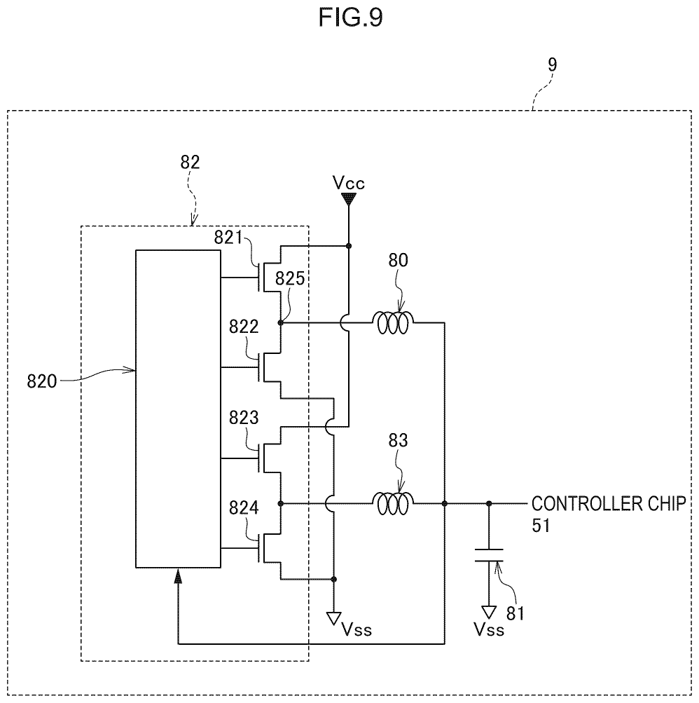

FIG. 9 is a circuit diagram illustrating the configuration of the power circuit 9 according to the present embodiment. As illustrated in FIG. 9, the power circuit 9 of the present embodiment further includes an inductor 83. In the following description, the inductor 80 is referred to as a first inductor 80, and the inductor 83 is referred to as a second inductor 83. The second inductor 83 is electrically connected in parallel to the first inductor 80.

The power device 82 further includes two switching elements 823 and 824 connected in series to each other. The switching elements 823 and 824 are connected to the second inductor 83. The switching elements 823 and 824 have configurations identical or similar to those of the switching elements 821 and 822, and thus detailed description thereof is omitted. The switching elements 823 and 824 are controlled by the control circuit 820.

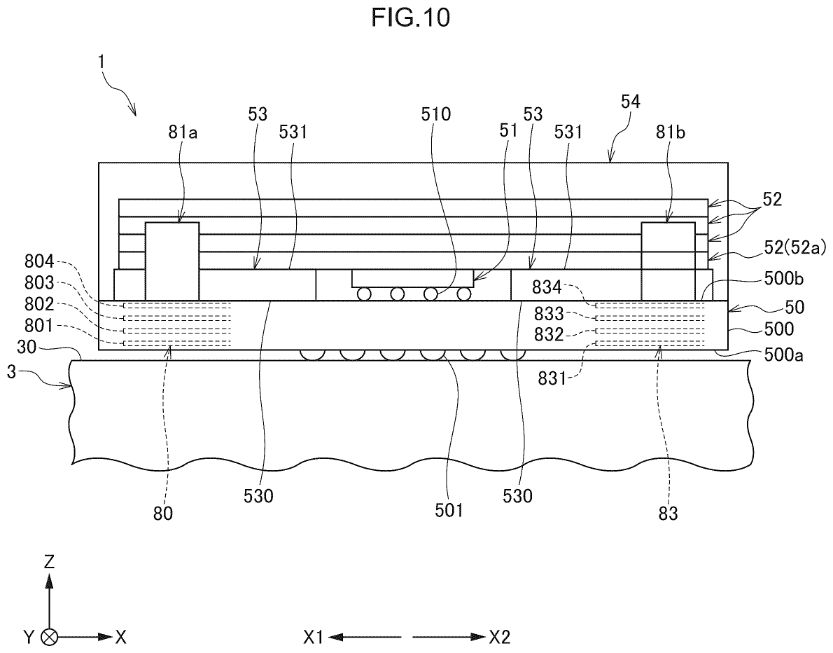

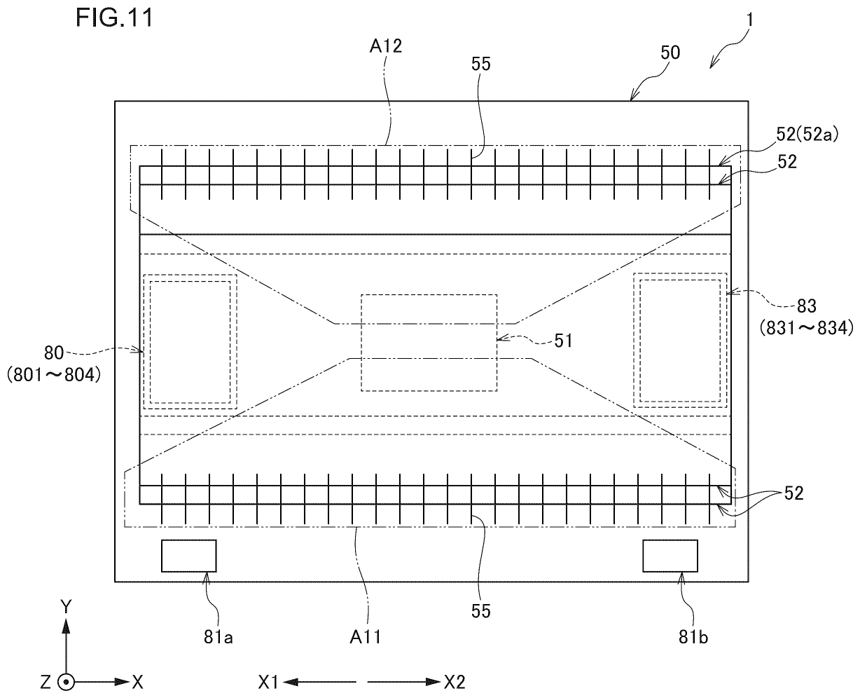

FIG. 10 is a front view illustrating the front structure of the semiconductor device 1 of the present embodiment. FIG. 11 is a plan view illustrating the planar structure of the semiconductor device 1 of the present embodiment. In FIGS. 10 and 11, one direction along the X direction is referred to as an X1 direction, and the other direction along the X direction is referred to as an X2 direction. The X1 direction is an example of a second direction. The X2 direction is an example of a third direction.

As illustrated in FIGS. 10 and 11, the second inductor 83 is disposed on the opposite side of the first inductor 80 with respect to the controller chip 51 in the X direction. The second inductor 83 is constituted by coil patterns 831 to 834 respectively formed in the wiring layers of the interposer substrate 50. The coil patterns 831 to 834 of the second inductor 83 have shapes identical or similar to those of the coil patterns 801 to 804 of the first inductor 80 respectively, and thus detailed description thereof is omitted. The coil patterns 801 to 804 are examples of a first coil pattern. The coil patterns 831 to 834 are examples of a second coil pattern.

A capacitor 81a corresponding to the first inductor 80 as well as a capacitor 81b corresponding to the second inductor 83 are provided on the upper surface 500b of the interposer substrate 50. In the following description, the capacitor 81a is referred to as a first capacitor 81a, and the capacitor 81b is referred to as a second capacitor 81b. As illustrated in FIG. 11, the second capacitor 81b is disposed alongside the second inductor 83 in the Y direction.

Note that, in the circuit diagram of the power circuit 9 illustrated in FIG. 9, the first capacitor 81a and the second capacitor 81b are collectively illustrated as one capacitor 81.

The control circuit 820 operates the switching elements 821 and 822, which are connected to the first inductor 80, and the switching elements 823 and 824, which are connected to the second inductor 83, in an interleaved manner by operating the switching elements 821 and 822 and the switching elements 823 and 824 with phases shifted from each other by 180°. The switching elements 821 and 822 are examples of a first switching element. The switching elements 823 and 824 are examples of a second switching element.

### 3.2 Effects of Semiconductor Device of Present Embodiment

The plurality of inductors 80 and 83 are formed in the interposer substrate 50. The first inductor 80 is displaced relative to the controller chip 51 in the X1 direction. The second inductor 83 is displaced relative to the first inductor 80 in the X2 direction that is opposite the X1 direction beyond the controller chip 51.

With this configuration, variation of output voltage can be reduced through 2-interleave operation. Moreover, characteristic degradation due to magnetic coupling can be reduced since the inductors 80 and 83 are apart from each other.

### 4 Other Embodiments

The present disclosure is not limited to the above-described specific examples.

For example, coil patterns constituting the inductor 80 do not need to be formed in all of the four wiring layers of the interposer substrate 50 but may be formed, for example, only in three of the wiring layers.

Although FIG. 5A exemplarily illustrates the configuration in which the second end part 801b of the coil pattern 801 and the first end part 802a of the coil pattern 802 protrude inward (in the positive Y direction), the second end part 801b of the coil pattern 801 and the first end part 802a of the coil pattern 802 may be formed to protrude outward (in the negative Y direction). This is also the same for the second end part 802b of the coil pattern 802, the first end part 803a and the second end part 803b of the coil pattern 803, and the first end part 804a of the coil pattern 804.

Although the interposer substrate 50 of each embodiment includes four wiring layers, the number of wiring layers included in the interposer substrate 50 is optionally changeable. In addition, the number of coil patterns constituting the inductor 80 is optionally changeable in accordance with the number of wiring layers. For example, in a case where four or more wiring layers are formed in the interposer substrate 50, the inductor 80 may be constituted by four or more coil patterns formed in the four or more wiring layers, respectively, of the interposer substrate 50.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
an interposer substrate including a plurality of wiring layers inside;
a first semiconductor chip disposed on the interposer substrate; and
a power circuit configured to transform externally supplied voltage and supply the transformed voltage to the first semiconductor chip,
wherein the power circuit includes:
an inductor constituted by a plurality of coil patterns respectively formed in at least two of the plurality of wiring layers of the interpose substrate; and
a capacitor.

2. The semiconductor device according to claim 1, wherein
the interposer substrate includes four or more wiring layers as the plurality of wiring layers, and
the inductor is constituted by four or more coil patterns respectively formed in the four or more wiring layers of the interposer substrate.

3. The semiconductor device according to claim 1, wherein the plurality of coil patterns are respectively formed in all of the plurality of wiring layers of the interposer substrate.

4. The semiconductor device according to claim 1, wherein
the plurality of wiring layers are stacked in a first direction and formed inside the interposer substrate, and
the plurality of coil patterns include no part overlapping the first semiconductor chip when viewed from the first direction.

5. The semiconductor device according to claim 1, wherein
the plurality of wiring layers are stacked in a first direction and formed inside the interposer substrate, and
the plurality of coil patterns are disposed at positions overlapping one another when viewed from the first direction.

6. The semiconductor device according to claim 1, wherein the first semiconductor chip includes a switching element of the power circuit and a control circuit configured to control the switching element.

7. The semiconductor device according to claim 1, further comprising a second semiconductor chip different from the first semiconductor chip, wherein
the second semiconductor chip includes a switching element of the power circuit and a control circuit configured to control the switching element.

8. The semiconductor device according to claim 1, further comprising a memory chip, wherein
the first semiconductor chip is a controller chip configured to control the memory chip.

9. The semiconductor device according to claim 8, wherein
the plurality of wiring layers are stacked in a first direction and formed inside the interposer substrate, and
the plurality of coil patterns are disposed at positions overlapping the memory chip when viewed from the first direction.

10. The semiconductor device according to claim 1, further comprising:
a memory chip; and
a spacer disposed between the memory chip and the interposer substrate, wherein
the first semiconductor chip is a controller chip configured to control the memory chip,
the plurality of wiring layers are stacked in a first direction and formed inside the interposer substrate,
the memory chip is disposed apart from a principal surface of the interposer substrate in the first direction, and
the plurality of coil patterns are disposed at positions overlapping the spacer when viewed from the first direction.

11. The semiconductor device according to claim 1, wherein the power circuit is configured to flow current through the plurality of coil patterns in identical rotational directions.

12. The semiconductor device according to claim 1, wherein the plurality of coil patterns are each formed in a rectangular shape.

13. The semiconductor device according to claim 1, wherein the plurality of coil patterns are each formed in a swirl shape.

14. The semiconductor device according to claim 1, wherein the power circuit includes at least two of the inductors.

15. The semiconductor device according to claim 14, wherein
the plurality of wiring layers are stacked in a first direction and formed inside the interposer substrate, and
the power circuit includes, as the at least two inductors,
a first inductor constituted by a plurality of first coil patterns and displaced relative to the first semiconductor chip in a second direction orthogonal to the first direction, and
a second inductor constituted by a plurality of second coil patterns and displaced relative to the first inductor in a third direction that is opposite the second direction beyond the first semiconductor chip.

16. The semiconductor device according to claim 15, further comprising at least two switching elements including a first switching element and a second switching element, wherein
the first switching element and the second switching element are connected to the first inductor and the second inductor, respectively, and
the power circuit operates the first switching element and the second switching element in an interleaved manner.

17. The semiconductor device according to claim 1, wherein
the plurality of wiring layers are stacked in a first direction and formed inside the interposer substrate, and
one of the plurality of coil patterns and another one of the plurality of coil patterns are connected each other through a through-hole formed to extend in the first direction in the interposer substrate.

18. The semiconductor device according to claim 17, further comprising:
a first switching element to which the externally supplied voltage is applied; and
a second switching element to which ground voltage is supplied, wherein
the one of the plurality of coil patterns has a first end and a second end,
the first end of the one of the plurality of coil patterns is connected to said another one of the plurality of coil patterns through the through-hole, and
the second end of the one of the plurality of coil patterns is connected to a node between the first switching element and the second switching element.

19. The semiconductor device according to claim 18, wherein
said another one of the plurality of coil patterns has a third end and a fourth end,
the third end of said another one of the plurality of coil patterns is connected to the first end of the one of the plurality of coil patterns through the through-hole, and
the fourth end of said another one of the plurality of coil patterns is connected to the capacitor.

20. The semiconductor device according to claim 19, wherein
the fourth end of said another one of the plurality of coil patterns is also connected to the first semiconductor chip.
